(19) United States
(12) Patent Application Publication
(10) Pub. No.: US 2025/0173398 A1
(43) Pub. Date: May 29, 2025

(54) MATRIX COMPUTING METHOD AND APPARATUS

(71) Applicant: HUAWEI TECHNOLOGIES CO., LTD., Shenzhen (CN)

(72) Inventor: Tengyi Lin, Shanghai (CN)

(21) Appl. No.: 19/020,178

(22) Filed: Jan. 14, 2025

Related U.S. Application Data
(63) Continuation of application No. PCT/CN2023/102182, filed on Jun. 25, 2023.

(30) Foreign Application Priority Data
Jul. 15, 2022 (CN) 202210835952.X

(51) Int. Cl. G06F 17/16

(52) U.S. Cl. CPC G06F 17/16

(57) ABSTRACT

In the matrix computing method, block division is performed by row on input data of a to-be-multiplied first matrix at a granularity of a subblock whose scale is M×N, to obtain at least one first subblock; and block division is performed by column on input data of a to-be-multiplied second matrix at a granularity of a subblock whose scale is N×R, to obtain at least one second subblock. One or more target subblock combinations are determined, where each target subblock combination includes one first subblock and one second subblock, and at least one element in the first subblock and at least one element in the second subblock in each target subblock combination are to-be-multiplied elements. Each of the one or more target subblock combinations is used as input data of a matrix computing apparatus, to obtain a product result of the first matrix and the second matrix.

### CROSS-REFERENCE TO RELATED APPLICATIONS

This application is a continuation of International Application No. PCT/CN2023/102182, filed on Jun. 25, 2023, which claims priority to Chinese Patent Application No. 202210835952.X, filed on Jul. 15, 2022. The disclosures of the aforementioned applications are hereby incorporated by reference in their entireties.

### TECHNICAL FIELD

This application relates to the field of sparse matrix technologies, and in particular, to a matrix computing method and apparatus.

### BACKGROUND

A matrix multiplication is a basic algorithm for a digital signal, and is also a basic operation of many scientific computing methods. The matrix multiplication is widely used in the fields such as digital image processing, computer vision fast processing and industrial real-time control. However, in an actual application, a matrix scale is usually large, and a matrix multiplication algorithm has high complexity and low processing efficiency, which becomes a bottleneck that restricts system performance improvement. Therefore, designing a high-performance hardware structure for such an application is a current research hot issue of a chip.

Although many matrix multiplication accelerator designs are proposed in recent years, there is a lack of discussion and support for acceleration of a non-uniform sparse matrix. A sparse matrix means that most elements are zero and non-zero elements are distributed irregularly. This even sparse matrix usually has a large scale, and is widely used in many modern application fields such as the hot fields, for example, artificial intelligence, big data, and image processing, and the fields, for example, computational fluid dynamics, statistical physics, circuit simulation, image processing, and even cosmic exploration. In these application fields, a matrix multiplication operation occupies a main part of a computing amount.

Storage resources and computing resources on a chip are very limited. Therefore, currently, a matrix multiplication operation for a sparse matrix is mainly implemented in a software manner, and a speed in a computing process is slow, which cannot meet a real-time processing requirement. Therefore, providing a matrix multiplication accelerator that supports the sparse matrix, to obtain higher computing efficiency and better adapt to an acceleration requirement of a modern application has become a key technical issue to be urgently resolved.

### SUMMARY

This application provides a matrix computing method and apparatus, to accelerate a multiplication operation of a sparse matrix.

According to a first aspect, an embodiment of this application provides a matrix computing method. The method includes: for a to-be-multiplied first matrix and a to-be-multiplied second matrix, performing, by row, block division on input data of the first matrix at a granularity of a subblock whose scale is M×N, to obtain at least one subblock (denoted as a first subblock), and performing, by column, block division on input data of the second matrix at a granularity of a subblock whose scale is N×R, to obtain at least one subblock (denoted as a second subblock), where all M, N, and R are positive integers; determining one or more target subblock combinations, where each target subblock combination includes one first subblock and one second subblock, and at least one element in the first subblock and at least one element in the second subblock in each target subblock combination are to-be-multiplied elements; and using each of the one or more target subblock combinations as input data of a matrix computing apparatus, to obtain a product result of the first matrix and the second matrix that is output by the matrix computing apparatus.

According to the foregoing design, the input data of the first matrix is divided into one or more first subblocks by row. The input data of the second matrix is divided into one or more second subblocks by column. The one or more target subblock combinations are determined based on data included in each first subblock and data included in each second subblock. The first subblock and the second subblock in each target subblock combination are used as the input data of the matrix computing apparatus, to obtain the product result of the first subblock and the second subblock. The input data of the first matrix may be a sparse code of the first matrix, or the input data of the second matrix may be a sparse code of the second matrix. Block division is performed on the input data of the first matrix and the input data of the second matrix, and a product result of each target subblock combination is computed based on the matrix computing apparatus, to complete a multiplication operation of the first matrix and the second matrix. This can accelerate a multiplication operation of a sparse matrix that is on any scale, has any spareness, and has a random distribution of non-zero elements.

In a possible implementation, the first matrix is a sparse matrix. The input data of the first matrix includes a value of a non-zero element of the first matrix and location information of the non-zero element. The location information indicates a location of the non-zero element in the first matrix. The second matrix is a dense matrix. The input data of the second matrix includes a value of an element of the second matrix and location information of the element. The location information indicates a location of the element in the second matrix.

According to the foregoing design, in this application, a multiplication operation of the sparse matrix and the dense matrix can be accelerated.

In a possible implementation, the first matrix is a sparse matrix. The input data of the first matrix includes a value of a non-zero element of the first matrix and location information of the non-zero element. The location information indicates a location of the non-zero element in the first matrix. The second matrix is a sparse matrix. The input data of the second matrix includes a value of a non-zero element of the second matrix and location information of the non-zero element. The location information indicates a location of the non-zero element in the second matrix.

According to the foregoing design, in this application, a multiplication operation of the sparse matrix and the sparse matrix can be accelerated.

In a possible implementation, the input data of the first matrix is a sparse code of the first matrix. The sparse code is obtained by coding an element in the first matrix.

According to the foregoing design, when the first matrix is sparsely coded, internal storage space required for storing and operating the first matrix can be reduced.

In a possible implementation, a format of the sparse code of the first matrix includes a compressed sparse row CSR format and a coordinate COO format.

According to the foregoing design, when the input data of the first matrix is the sparse code in the CSR or COO format, block division can be performed on the input data of the first matrix more conveniently and quickly by row.

In a possible implementation, if the second matrix is a sparse matrix, the input data of the second matrix is a sparse code of the second matrix. The sparse code is obtained by coding an element in the second matrix.

According to the foregoing design, when the second matrix is sparsely coded, internal storage space required for storing and operating the second matrix can be reduced.

In a possible implementation, a format of the sparse code of the second matrix includes the compressed sparse column CSC format and a coordinate COO format.

According to the foregoing design, when the input data of the second matrix is the sparse code in the CSC or COO format, block division can be performed on the input data of the second matrix more conveniently and quickly by column.

In a possible implementation, the location information indicates a row number and a column number of the non-zero element. The to-be-multiplied element means that a column number of an element in the first subblock is the same as a row number of an element in the second subblock.

According to the foregoing design, the to-be-multiplied elements are determined based on the location information of the non-zero element in the first subblock and the location information of the non-zero element in the second subblock.

In a possible implementation, the determining one or more target subblock combinations includes:
dividing the at least one first subblock and the at least one second subblock into a plurality of subblock combinations, where each subblock combination includes any first subblock and any second subblock;
for each subblock combination, determining a column number range of an element in the first subblock in the subblock combination and a row number range of an element in the second subblock in the subblock combination; and
if there is an intersection between the column number range and the row number range, determining that the subblock combination is the target subblock combination; or if there is no intersection between the column number range and the row number range, determining that the subblock combination is not the target subblock combination.

According to the foregoing design, when the to-be-multiplied elements are determined, a column number range of the first subblock and a row number range of the second subblock are compared, to greatly reduce a quantity of comparison times, and further shorten data preparation duration, so as to shorten matrix multiplication operation duration.

In a possible implementation, the matrix computing apparatus is configured to compute a product result of the first subblock and the second subblock based on the input to-be-multiplied elements in the first subblock and the second subblock.

According to the foregoing design, the matrix computing apparatus provided in this application can identify the to-be-multiplied elements in the first subblock and the second subblock, and perform a multiplication operation on the to-be-multiplied elements. In this way, the matrix computing apparatus can support a multiplication operation of a sparse matrix multiplication operation, and can improve efficiency of the multiplication operation.

In a possible implementation, the matrix computing apparatus determines the product result of the first matrix and the second matrix in the following manner:
dividing all the target subblock combinations into a plurality of sets, where one or more first subblocks included in one or more target subblock combinations in each set are located in a same row of the first matrix, and one or more second subblocks included in the one or more target subblock combinations in each set are located in a same column of the second matrix; and for each set, sequentially inputting the one or more target subblock combinations in the set into the matrix computing apparatus, and computing, by the matrix computing apparatus, a product result of each target subblock combination, and adding product results of the one or more target subblock combinations in the set, where an addition result is one subblock in the product result of the first matrix and the second matrix.

According to the foregoing design, the matrix computing apparatus provided in this application can add product results of a plurality of target subblock combinations, to obtain the product result of the first matrix and the second matrix.

According to a second aspect, an embodiment of this application provides a matrix computing apparatus. The matrix computing apparatus includes an input interface, a comparison unit, and a computing unit.

The input interface is configured to obtain input data of a to-be-multiplied first submatrix and input data of a to-be-multiplied second submatrix. The input data of the first submatrix includes a value of an element in the first submatrix and location information indicating a location, in a first matrix, of a non-zero element in the first submatrix. The input data of the second submatrix includes a value of an element in the second submatrix and location information indicating a location, in a second matrix, of a non-zero element in the second submatrix.

The comparison unit is configured to compare location information of any non-zero element in the first submatrix with location information of any non-zero element in the second submatrix, to determine one or more pairs of to-be-multiplied elements in the first submatrix and the second submatrix.

The computing unit is configured to perform a multiply-add operation on the one or more pairs of to-be-multiplied elements, to obtain a product result of the first submatrix and the second submatrix.

In a possible implementation, the location information includes a row number and a column number of the non-zero element.

The comparison unit is specifically configured to: compare whether a column number of any element in the first submatrix is the same as a row number of any element in the second submatrix; and if the column number of the any element in the first submatrix is the same as the row number of the any element in the second submatrix, determine that the any element in the first submatrix and the any element in the second submatrix are a pair of to-be-multiplied elements, or if the column number of the any element in the first submatrix is different from the row number of the any element in the second submatrix, determine that the any element in the first submatrix and the any element in the second submatrix are not to-be-multiplied elements.

In a possible implementation, when performing the multiply-add operation on the one or more pairs of to-be-multiplied elements, the computing unit is specifically configured to:
perform, based on any row vector in the first submatrix and any column vector in the second submatrix, the multiply-add operation on a to-be-multiplied element included in the row vector and a to-be-multiplied element included in the column vector, to obtain a vector multiply-add result of the row vector and the column vector, where the vector multiply-add result is an element in the product result of the first submatrix and the second submatrix.

In a possible implementation, the computing unit is further configured to: add the product result to a third submatrix stored in an accumulator, and write an addition result back to the accumulator.

In a possible implementation, the matrix computing apparatus further includes a detection module. The detection module is configured to detect whether the first submatrix and the second submatrix are overlap matrices. The overlap matrices mean that at least one element in the first submatrix and at least one element in the second subblock are to-be-multiplied elements.

In a possible implementation, the to-be-multiplied element means that a column number of an element in the first subblock is the same as a row number of an element in the second subblock.

In a possible implementation, the comparison unit includes at least one comparator.

According to a third aspect, an embodiment of this application provides a matrix acceleration apparatus. The apparatus includes a processor and a matrix computing apparatus.

The processor is configured to: perform, by row, block division on input data of a to-be-multiplied first matrix at a granularity of a subblock whose scale is M×N, to obtain at least one first subblock, and perform, by column, block division on input data of a to-be-multiplied second matrix at a granularity of a subblock whose scale is N×R, to obtain at least one second subblock, where all M, N, and R are positive integers; determine one or more target subblock combinations, where each target subblock combination includes one first subblock and one second subblock, and at least one element in the first subblock and at least one element in the second subblock in each target subblock combination are to-be-multiplied elements; and input each of the one or more target subblock combinations into the matrix computing apparatus.

The matrix computing apparatus is configured to compute a product result of the first subblock and the second subblock based on the input to-be-multiplied elements in the first subblock and the second subblock in each target subblock combination.

According to a fourth aspect, this application further provides a computing apparatus. The apparatus includes a processor, a memory, and a matrix computing apparatus. The processor executes program instructions in the memory to perform the method according to any one of the first aspect and the possible implementations of the first aspect. The memory is coupled to the processor, and stores program instructions and data that are necessary for performing a data backup process. The matrix computing apparatus is configured to implement the functions of the matrix computing apparatus according to the second aspect.

According to a fifth aspect, this application further provides a computing apparatus. The computing apparatus includes a processor, a memory, and a matrix computing apparatus. The processor performs the method according to any one of the first aspect and the possible implementations of the first aspect, or performs the method according to any one of the second aspect and the possible implementations of the second aspect, or performs the method according to any one of the third aspect and the possible implementations of the third aspect. A communication interface is configured to communicate with another device.

### BRIEF DESCRIPTION OF DRAWINGS

FIG. 1 is a diagram of a compressed sparse row format;

FIG. 2 is a diagram of a compressed sparse column format;

FIG. 3 is a diagram of a structure of a matrix accelerator;

FIG. 4 is a schematic flowchart of a structured pruning algorithm;

FIG. 5 is a diagram of an application scenario of a graph neural network;

FIG. 6 is a schematic flowchart corresponding to a matrix computing method according to an embodiment of this application;

FIG. 7 is an instance of a matrix computing method according to an embodiment of this application;

FIG. 8 is a diagram of a structure of a matrix computing apparatus 10 according to an embodiment of this application;

FIG. 9 is a diagram of a structure of a matrix computing apparatus 10 according to an embodiment of this application;

FIG. 10 is a diagram of a structure of another matrix computing apparatus 10 according to an embodiment of this application;

FIG. 11 is a schematic flowchart of performing a subblock multiplication operation based on a matrix computing apparatus 10 according to an embodiment of this application; and

FIG. 12 is a diagram of a structure of a computing device according to an embodiment of this application.

### DESCRIPTION OF EMBODIMENTS

To better explain embodiments of this application, related terms or technologies in this application are first explained.

### 1. Row Vector

The row vector is a 1×m matrix, where m is any positive integer, for example, x=[x₁ x₂ . . . xₘ].

### 2. Column Vector

The column vector is an n×1 matrix, where n is any positive integer, for example,

$$x = [ \begin{matrix}{x}_{1} \\ {x}_{2} \\ … \\ {x}_{n}\end{matrix} ] .$$

### 3. Matrix Size/Scale

An m×n matrix is a rectangular array formed by arranging m rows and n columns of elements. For example,

$$A = [ \begin{matrix}{A}_{11} & {A}_{12} & … & {A}_{1 n} \\ {A}_{21} & {A}_{22} & … & {A}_{2 n} \\ … & … & … & … \\ {A}_{m 1} & {A}_{m 2} & … & {A}_{mn}\end{matrix} ] .$$

Each number that constitutes the matrix is referred to as an element of the matrix. For example, all A₁₁, A₁₂, and Aₘₙ are elements of the matrix A. A subscript (or referred to as coordinates) of the element indicates a location, in the matrix, of the element, and may be a row number (or referred to as a row coordinate) and a column number (or referred to as a column coordinate), in the matrix, of the element. For example, A₁₁ indicates that the element is located in a 1^{st} row and a 1^{st} column of the matrix A, and A₂₁ indicates that the element is located in a 2^{nd} row and the 1^{st} column of the matrix A. In addition, the subscript may alternatively be in a different representation form. For example, A₁₁ may alternatively be written as A_{1,1}, and A₂₁ may alternatively be written as A_{2,1}. A similar part is not described again in the following.

### 4. Matrix Addition (Matrix Addition)

The matrix addition means adding two matrices with a same scale (or referred to as a same size, where to be specific, the two matrices have a same quantity of rows (rows) and a same quantity of columns (columns)). Certainly, a matrix subtraction may alternatively be performed. Specifically, addition or subtraction is performed on elements at a same location in each of the two matrices. In the following, A and B are each an m×n matrix, and A+B=a matrix C.

$$A = [ \begin{matrix}{A}_{11} & {A}_{12} & … & {A}_{1 n} \\ {A}_{21} & {A}_{22} & … & {A}_{2 n} \\ … & … & … & … \\ {A}_{m 1} & {A}_{m 2} & … & {A}_{mn}\end{matrix} ]$$

$$B = [ \begin{matrix}{B}_{11} & {B}_{12} & … & {B}_{1 n} \\ {B}_{21} & {B}_{22} & … & {B}_{2 n} \\ … & … & … & … \\ {B}_{m 1} & {B}_{m 2} & … & {B}_{mn}\end{matrix} ]$$

$$and$$

$$C = A + B = [ \begin{matrix}{A}_{11} + {B}_{11} & {A}_{12} + {B}_{12} & … & {A}_{1 n} + {B}_{1 n} \\ {A}_{21} + {B}_{21} & {A}_{22} + {B}_{22} & … & {A}_{2 n} + {B}_{2 n} \\ … & … & … & … \\ {A}_{m 1} + {B}_{m 1} & {A}_{m 2} + {B}_{m 2} & … & {A}_{mn} + {B}_{mn}\end{matrix} ]$$

### 4. Matrix Multiplication (Matrix Multiplication)

For two to-be-multiplied matrices (for example, matrices A and B), it is required that a quantity of columns of A is the same as a quantity of rows of B. For example, if A is an m×n matrix and B is an n×r matrix, a product of A and B is an m×r matrix. For example,

$$A = [ \begin{matrix}{a}_{11} & {a}_{12} & {a}_{13} \\ {a}_{21} & {a}_{22} & {a}_{23}\end{matrix} ] ,$$

$$B = [ \begin{matrix}{b}_{11} & {b}_{12} \\ {b}_{21} & {b}_{22} \\ {b}_{31} & {b}_{32}\end{matrix} ] ,$$

$$and$$

$$C = AB = [ \begin{matrix}{a}_{11} {b}_{11} + {a}_{12} {b}_{21} + {a}_{13} {b}_{31} & {a}_{11} {b}_{12} + {a}_{12} {b}_{22} + {a}_{13} {b}_{32} \\ {a}_{21} {b}_{11} + {a}_{22} {b}_{21} + {a}_{23} {b}_{31} & {a}_{21} {b}_{12} + {a}_{22} {b}_{22} + {a}_{23} {b}_{32}\end{matrix} ] .$$

### 5. Sparse Matrix (Sparse Matrix)/Dense Matrix (Dense Matrix)

A matrix is classified as the sparse matrix or the dense matrix based on a proportion of a non-zero element (Number of Non-zero Element) in the matrix. If most elements in the matrix are non-zero elements, the matrix is the dense matrix. On the contrary, if most elements in the matrix are zero, the matrix is the sparse matrix. Spareness is used to reflect the proportion of the non-zero element in the sparse matrix. Higher spareness indicates a lower proportion of the non-zero element. The following is an example of a sparse matrix.

| | | | | | | |
|---|---|---|---|---|---|---|
| 0 | 7 | 0 | 0 | 0 | 0 | 6 |
| 0 | 7 | 6 | 3 | 0 | 4 | 0 |
| 0 | 4 | 3 | 0 | 0 | 0 | 0 |
| 4 | 2 | 0 | 0 | 0 | 0 | 0 |
| 0 | 0 | 0 | 0 | 3 | 2 | 4 |

A large matrix requires a large-capacity internal storage for storage, but most elements in a sparse matrix are 0. Therefore, when a computer stores and operates the sparse matrix, an element of the sparse matrix is usually coded as a sparse code. The sparse code includes only information about a non-zero element. Internal storage costs of operating the sparse matrix are reduced by storing the sparse code of the sparse matrix. Common formats of the sparse code include a coordinate (coordinate, COO) format, a compressed sparse row (compressed sparse row, CSR) format, and a compressed sparse column (compressed sparse column, CSC) format.
(1) In the coordinate COO format, the sparse matrix is represented by using a triplet. The triplet includes a row number, a column number, and an element value. The row number and the column number identify a location of the element value. The following shows a simple sparse matrix for description.

| | | |
|---|---|---|
| 1 | 0 | 0 |
| 0 | 0 | 6 |
| 3 | 0 | 0 |

For the sparse matrix, the following information may be stored in a format of (value, row, column):
(1, 1, 1), where a value of an element is 1, and a subscript of the element is (1, 1);
(3, 3, 1), where a value of an element is 3, and a subscript of the element is (3, 1); and
(6, 2, 3), where a value of an element is 6, and a subscript of the element is (2, 3).

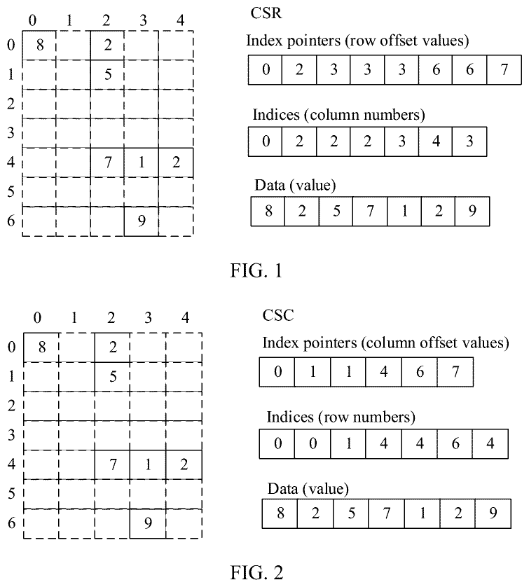

Certainly, the foregoing information may alternatively be stored in another format, for example, (row, column, values). This is not specifically limited.
(2) In the compressed sparse row CSR format, the sparse matrix is represented by using three types of data. The three types of data are respectively an element value, a column number, and a row offset value. A difference between the CSR and the COO lies in that the row offset value is used instead of the row number. FIG. 1 shows an example of a compressed sparse row format.
(3) In the compressed sparse column CSC format, the sparse matrix is represented by using three types of data. The three types of data are respectively an element value, a row number, and a column offset value. A difference between the CSC and the COO lies in that the column offset value is used instead of the column number. FIG. 2 shows an example of a compressed sparse row format.

The foregoing describes three compression formats of the sparse matrix. Correspondingly, a matrix in an uncompressed format is generally referred to as a dense matrix. The dense matrix includes only a value of a matrix element, but coordinates of the element are not stored.

### 6. Multiply Accumulate (Multiply Accumulate, MAC) Operation

The multiply accumulate operation is a special operation in a digital signal processor or some microprocessors, for example, a matrix multiplication operation or a matrix addition operation. A hardware circuit unit that implements the operation is referred to as a “multiplier-accumulator”. This operation is to add a product result of a multiplication to a value of the accumulator, and then store an obtained result in the accumulator.

### 7. Arithmetic Intensity (Arithmetic Intensity, AI) Operation

The arithmetic intensity operation means a ratio of work W to internal storage traffic Q, that is, AI=W/Q, where Q indicates a quantity of operations per byte of internal storage traffic. When the work W is expressed as FLOPs, an obtained arithmetic intensity AI is a ratio (FLOPs/Byte) of a floating-point operation to a total data movement amount (FLOPs/Byte). A higher value of the AI indicates a higher data reuse rate.

### 8. Structured Sparsity/Unstructured Sparsity

Structured sparsity/unstructured sparsity is used to describe a distribution of zero elements in a matrix. Structured sparsity indicates that the distribution of the zero elements is even. It may be understood that, in a row vector per unit length in the matrix, structured sparsity means that a proportion of a zero element is the same. On the contrary, if a distribution of zero elements is random and uneven, the distribution is unstructured sparsity.

The following is an example of a matrix with structured sparsity. For example, a unit length is 1×6, and each row vector includes two non-zero elements.

| | | | | | |
|---|---|---|---|---|---|
| 0 | 7 | 0 | 0 | 0 | 8 |
| 0 | 0 | 6 | 3 | 0 | 0 |
| 5 | 0 | 0 | 0 | 7 | 0 |
| 4 | 0 | 0 | 9 | 0 | 0 |
| 0 | 0 | 5 | 0 | 3 | 0 |

The following shows a matrix with unstructured sparsity. Zero values of the matrix are generally distributed randomly and unevenly.

| | | | | | |
|---|---|---|---|---|---|
| 0 | 7 | 0 | 4 | 0 | 8 |
| 1 | 4 | 0 | 0 | 0 | 0 |
| 0 | 3 | 0 | 0 | 7 | 0 |
| 4 | 0 | 1 | 9 | 0 | 2 |
| 3 | 0 | 5 | 0 | 3 | 0 |

### 9. Neural Network

The neural network (neural network, NN) is an algorithmic mathematical model that imitates a behavior feature of an animal neural network and performs distributed parallel information processing. Information is processed by adjusting an interconnection relationship between a large quantity of nodes in the neural network.

Specifically, the neural network may usually include a plurality of layers, for example, a convolution layer, a fully connected layer (fully connected layer, FC), an activation layer, and a pooling layer, that are connected in a head-to-tail mode. Each layer may be expressed as a function y=f_{w}(x), where f is a function of the function. A derivative may be solved for the function f, w is a weight (or referred to as a weight matrix), x is an input (or referred to as an input matrix), and y is an output (or referred to as an output matrix). It should be understood that one layer of the neural network may include a plurality of neurons, and weight values of the plurality of neurons may be combined into one weight matrix. It can be learned that the neural network usually internally includes a large amount of matrix computing.

Matrix computing is an important computing type like neural network convolution computing in artificial intelligence computing, simultaneous equation solving in scientific computing, or algebraic graph computing. In an early phase, a general-purpose CPU is used for computing. In recent years, chip vendors provide various matrix accelerators to improve matrix computing power of a chip.

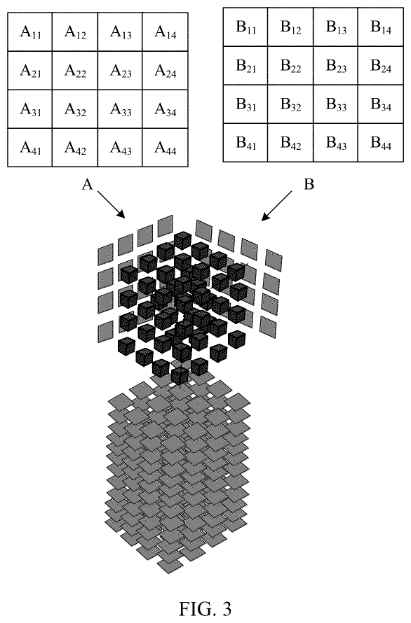

FIG. 3 is a diagram of a hardware structure of a matrix accelerator. As shown in FIG. 3, the matrix accelerator includes 64 MACs. In a unit time cycle, the matrix accelerator can complete a multiplication operation of a 4×4 matrix A and a 4×4 matrix B, to obtain a product result matrix C. Each MAC performs the multiplication operation on input values of two elements at fixed locations in two matrices. This matrix accelerator can usually effectively accelerate computing of a dense matrix.

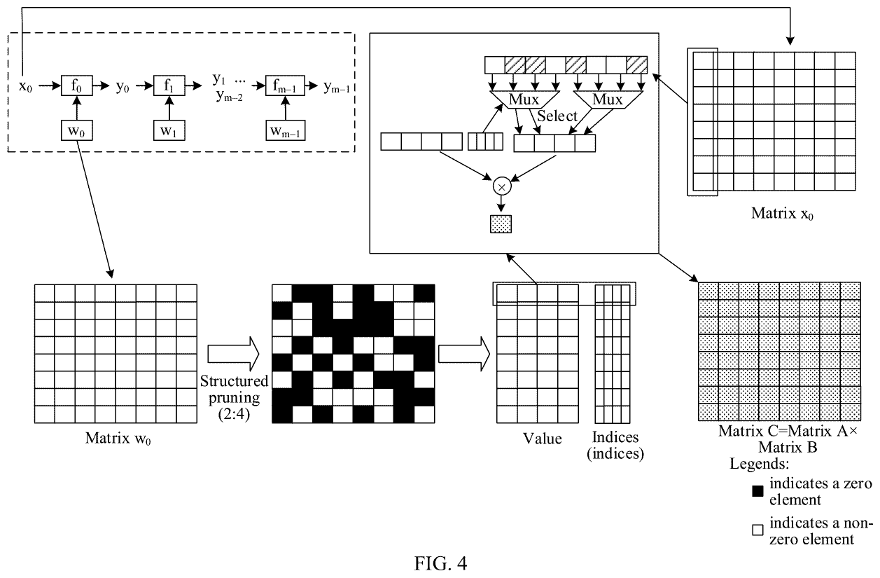

With emergence of the matrix accelerators, some algorithms for improving computing efficiency, for example, a pruning algorithm, also become research focuses. Currently, some matrix accelerators allow using the pruning algorithm to accelerate computing of a specific type of sparse matrix. FIG. 4 shows a scenario of accelerating a matrix operation with reference to the pruning algorithm.

First, a structure of a neural network shown in FIG. 4 is described. The neural network may include m layers that are connected in a head-to-tail mode, where m is an integer greater than or equal to 2. Each layer may be expressed as a function y=f_{w}(x). A 0^{th} layer of the neural network may be expressed as a function f₀, where for f₀, input data is a matrix x₀, a weight matrix is a matrix w₀, and an output matrix is a matrix y₀, for example, f₀=x₀·w₀=y₀; a 1^{st} layer of the neural network may be expressed as a function f₁, where for f₁, an input matrix is y₀, an output matrix is y₁, and a weight matrix is w₁, for example, f₁=y₀ w₁=y₁; and so on.

One layer is used as an example. If the neural network is used to process an image or video frame, the matrix x, may be obtained by converting a frame of to-be-processed image or a frame of image in the to-be-processed video. A person skilled in the art may know that the matrix x₀ is usually a dense matrix. A weight matrix, for example, the matrix w₀, includes values of weights that are trained at the 0^{th} layer of the neural network. A range of the value of the weight is generally (0, 1]. In other words, the matrix w₀ is also a dense matrix. It can be learned that the neural network internally includes a large quantity of matrix multiplication operations.

The following uses a computing process of the function f₀=x₀ w₀ as an example to describe an acceleration procedure of multiplication computing of the matrix. As shown in FIG. 4, both sizes of the matrix x, and the matrix w₀ are 8×8.
(1) A structured pruning algorithm is used to prune the matrix w₀ in a fixed proportion, for example, 2:4. Values of weights (elements) in each 1×4 row vector are sorted. Two weights with smaller values in the weights are removed, and values of the two weights are set to 0. As shown in FIG. 4, after structured pruning, the matrix w₀ is a structured sparse matrix, and a scale of a pruned matrix w₀ is 4×8.
(2) A row vector (denoted as a first row vector) corresponding to a 1^{st} row of the compressed matrix w₀ is extracted. Four elements are selected by using two data selectors (mux) from a column vector (denoted as a first column vector) corresponding to a 1^{st} column of the matrix x₀, to obtain a 4×1 column vector.
(3) A product of the 1×4 first row vector of the compressed matrix w₀ and the 4×1 column vector obtained by using the data selector are computed by using a matrix accelerator, where a product result is an element in the matrix y₀.

Another element in the matrix y₀ is obtained according to steps (1) to (3).

The matrix accelerator removes 50% of zero elements with reference to the pruning algorithm, to double computing efficiency.

Unstructured pruning (unstructured pruning) corresponds to structured pruning. In the foregoing example, during unstructured pruning, values of all elements in the matrix w₀ may be sorted, and 50% of elements with smaller values in all the elements are removed. It is clear that unstructured pruning may bring higher accuracy, but a pruned matrix is usually an unstructured sparse matrix. A current matrix accelerator supports only acceleration of a structured sparse matrix, but does not support acceleration of an unstructured sparse matrix. In addition, it should be noted that the matrix accelerator that supports computing of the structured sparse matrix can be applied only to a limited scenario (for example, convolution computing of a neural network). This is because, in the multiplication operation of the matrix shown in FIG. 4, only a weight matrix can be pruned, but an input matrix cannot be pruned. If the input matrix is pruned, accuracy of a product result of the input matrix cannot be ensured, and an error of a computing result may be increased.

Therefore, currently, in an application scenario of a graph (Graph) computing neural network, namely, a graph neural network (Graph Neural Network), an existing matrix accelerator is completely inapplicable. This is because an input matrix of the graph neural network usually includes a large-scale sparse matrix, and has very high spareness and a proportion of non-zero elements that is usually less than 1%. The current matrix accelerator cannot effectively accelerate a computing scenario of this sparse matrix, and only software can be used to complete computing of the sparse matrix.

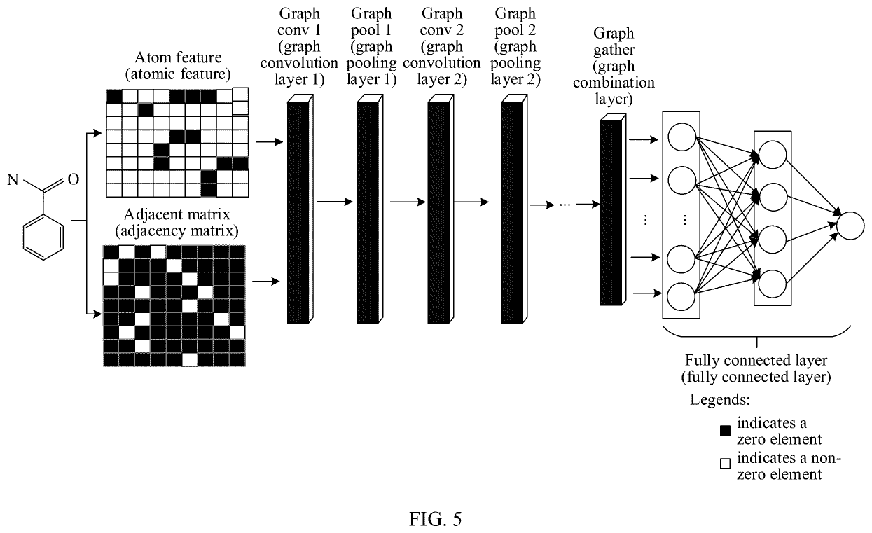

The graph neural network is widely used in many fields such as chemical molecular structures, gene sequencing, social networks, recommendation systems, and natural languages. For example, FIG. 5 is an application scenario of the graph neural network. The graph neural network is used to analyze a chemical molecular structure. The molecular structure shown in FIG. 5 includes nine atoms. An atom feature is an input matrix used to describe an atomic feature. Each column in the input matrix is a feature vector of an atom. An adjacency matrix is another input matrix used to describe a connection relationship between atoms. An element value that is 1 indicates that two atoms have a connection relationship. An element value that is 0 indicates that two atoms do not have a connection relationship. It can be learned that the atom feature matrix is a dense matrix, and the adjacency matrix is a sparse matrix and has high sparseness. Because the existing matrix accelerator cannot accelerate a computing scenario of this sparse matrix, currently, only the software can be used to complete computing of the sparse matrix. As a result, performance of the graph neural network is greatly different from that of a general graph neural network, and is dozens of times behind.

In conclusion, the existing matrix accelerator can support only dense matrix-matrix multiplication (GEMM) computing, or double a speed of computing of the specific type of sparse matrix with reference to the structured pruning algorithm, but cannot satisfy all pruning algorithms, and cannot support sparse general matrix-matrix multiplication (SpGEMM) computing in an unstructured pruning algorithm, graph computing, the graph neural network, scientific computing (HPC), and the like. In addition, a scenario in which the existing matrix accelerator can be used is excessively limited, most sparse matrix multiplication operations need to be completed by the software, and a computing speed is slow, resulting in lagging development of application technologies in many fields.

The following describes in detail a matrix computing method provided in embodiments of this application.

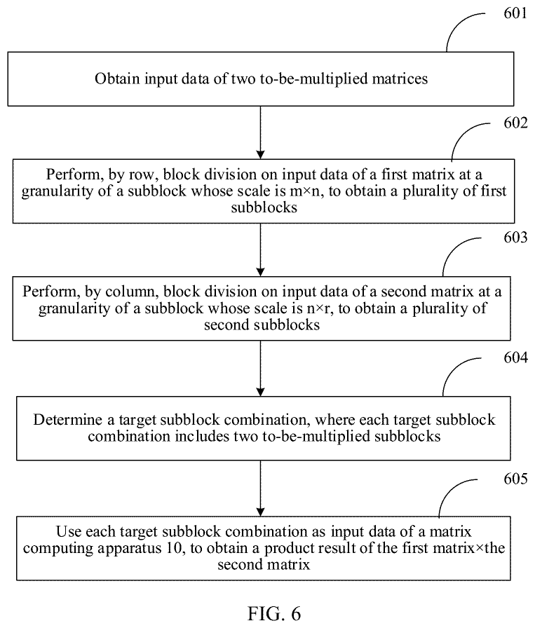

FIG. 6 is a schematic flowchart of a matrix computing method according to an embodiment of this application. As shown in FIG. 6, the method includes the following steps.
Step 601: Obtain input data of two to-be-multiplied matrices (denoted as a first matrix and a second matrix).

The first matrix may be a sparse matrix or a dense matrix, and the second matrix may be a sparse matrix or a dense matrix. In other words, the matrix computing method provided in this application may be used to compute a dense matrix×a dense matrix, a sparse matrix×a dense matrix, and a sparse matrix×a sparse matrix.

The following uses the sparse matrix (the first matrix)×the sparse matrix (the second matrix) as an example to describe in detail the matrix computing method. The input data of the first matrix includes a set of a value of a non-zero element in the first matrix and location information (for example, denoted as original coordinates/original subscripts, which is not described again in the following) indicating a location of the non-zero element in the first matrix. For example, the input data of the first matrix is a sparse code of the first matrix. A format of the sparse code may be any compressed sparse format, for example, a CSR format, a CSC format, or a COO format. Similarly, the input data of the second matrix includes a set of a value of a non-zero element in the second matrix and location information indicating a location of the non-zero element in the second matrix. For example, the input data of the second matrix is a sparse code of the second matrix. A format of the sparse code may be the any compressed sparse format, for example, the CSR format, the CSC format, or the COO format.
Step 602: Perform, by row, block division on the input data of the first matrix at a granularity of a subblock whose scale is m×n, to obtain a plurality of subblocks (for example, first subblocks). Herein, m and n each are a positive integer, and m may be equal to n.

A representation (denoted as a first compressed matrix) that is obtained by compressing the first matrix by row may be obtained based on the input data of the first matrix. For clarity, the following uses the first compressed matrix to demonstrate how to perform block division.

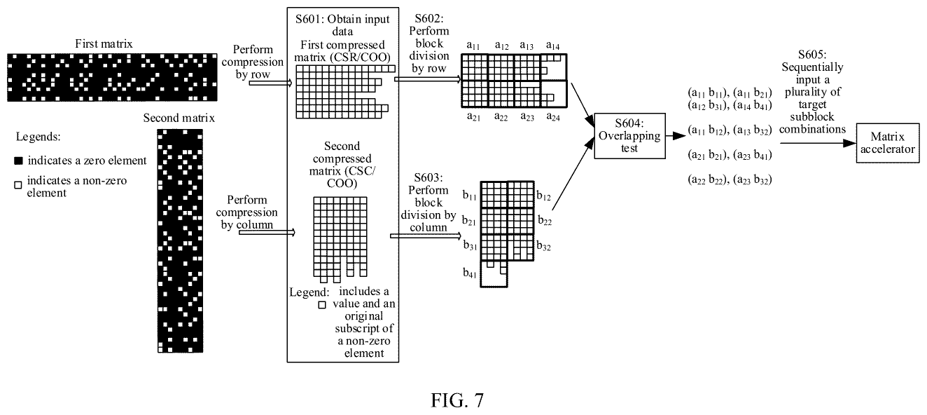

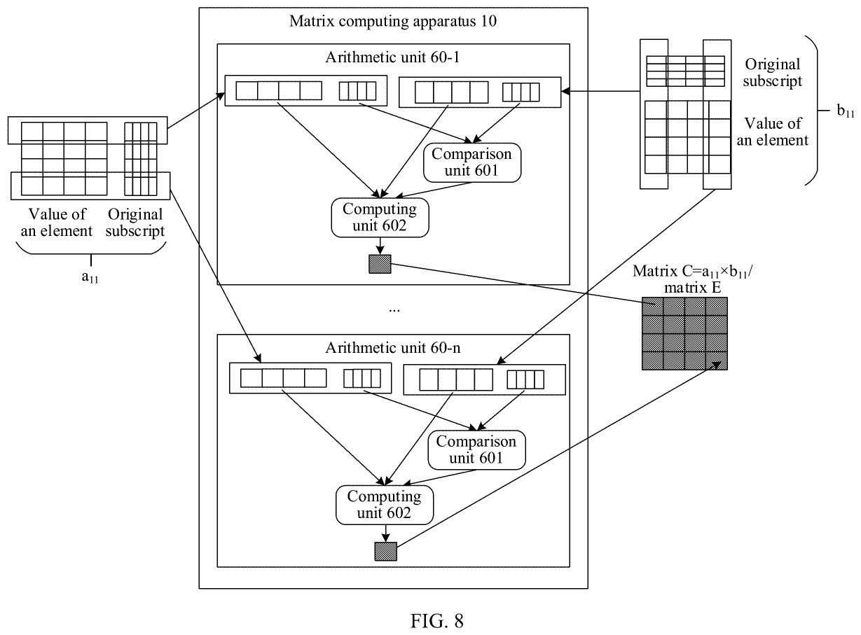

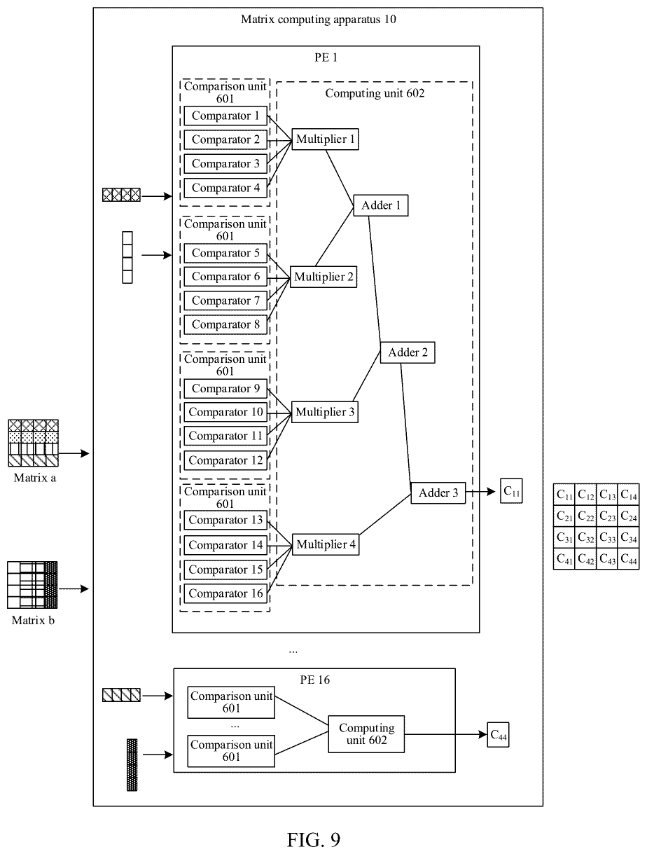

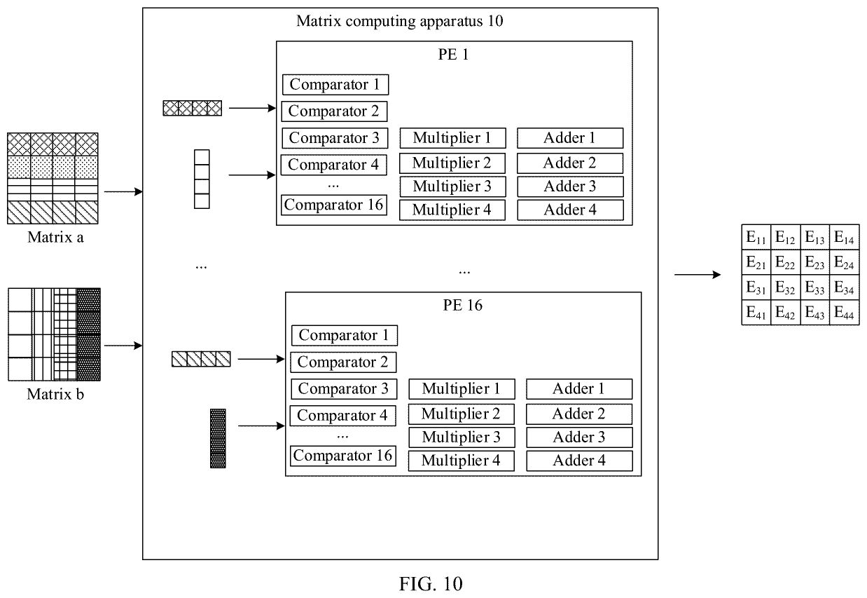

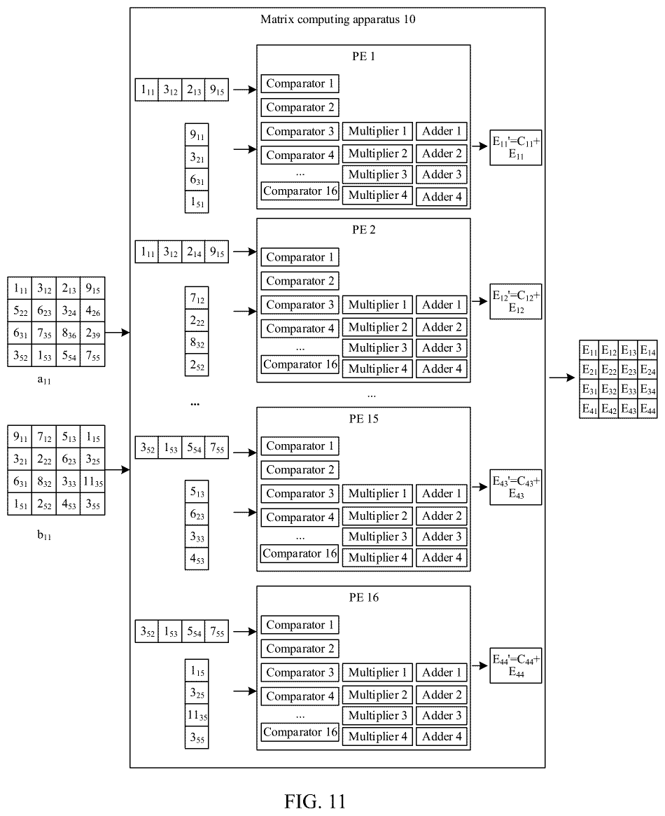

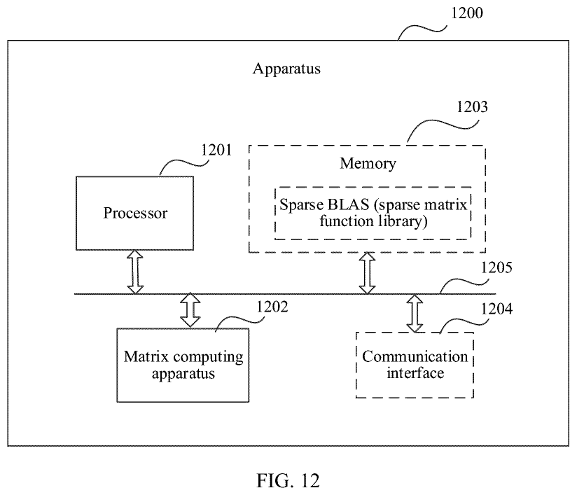

With reference to FIG. 7 for understanding. FIG. 7 shows an example of a process of obtaining the first compressed matrix by compressing (compressing to remove a zero element) the first matrix by row. The first compressed matrix may represent a state in which non-zero elements in the first matrix are arranged by row. For example, in the first compressed matrix shown in FIG. 7, elements in a same row have a same row number, and quantities of elements in different rows may not be equal, which is related to a quantity of non-zero elements included in each row of the first matrix. It should be noted that a row number herein is a row number, in the first matrix, of the non-zero element. Similarly, a column number of the non-zero element is a column number, in the first matrix, of the non-zero element. In addition, it should be noted that a quantity of rows of the first compressed matrix is less than or equal to a quantity of rows of the first matrix. For example, when one or more rows of all-zero elements exist in the first matrix, the one or more rows of all-zero elements are compressed by entire row. In this case, the quantity of rows of the first compressed matrix is less than the quantity of rows of the first matrix. If at least one non-zero element exists in each row of the first matrix, the quantity of rows of the first compressed matrix is equal to the quantity of rows of the first matrix. A matrix computing manner provided in this application is not affected by this case.

For example, it is assumed that block division is performed on the first compressed matrix by row at a granularity of a 4×4 subblock. As shown in FIG. 7, after block division, eight first subblocks are obtained. For example, the eight first subblocks are respectively marked as a11, a12, a13, a14, a21, a22, a23, and a24 based on a row-column relationship between the subblocks. Herein, aij indicates that the subblock is located in an i^{th} horizontal rank (or an i^{th} row) and a j^{th} vertical rank (or a j^{th} column) in the first compressed matrix. As shown in FIG. 7, a11, a12, a13, and a14 are subblocks located in a 1^{st} row in the first compressed matrix, and a21, a22, a23, and a24 are subblocks located in a 2^{nd} row of the first compressed matrix. During block division, if a quantity of elements at a boundary in the first compressed matrix is less than 4×4 (for example, a13, a14, a23, and a24), zeros are added to reach 4×4. Data of each subblock includes a matrix formed by the subblock and location information indicating a location, in the first matrix, of a non-zero element in the matrix.

It should be noted that the first compressed matrix in FIG. 7 is merely a structure shown for easy of understanding “block division”. During actual application, the sparse code of the first matrix may be stored in a memory (for example, an internal storage). In this application, block division may be directly performed based on the sparse code of the first matrix in the CSR or COO format. If the input data of the first matrix is the sparse code in the CSC format, the input data may be first converted into the sparse code in the COO or CSR format, and then block division is performed.
Step 603: Perform, by column, block division on the input data of the second matrix at a granularity of a subblock whose scale is n×r, to obtain a plurality of subblocks (for example, second subblocks). Herein, n and r each are a positive integer, and n may be equal to r.

A representation (denoted as a second compressed matrix) that is obtained by compressing the second matrix by column may be obtained based on the input data of the second matrix. For clarity, the following uses the second compressed matrix to demonstrate how to perform block division.

Still refer to FIG. 7. FIG. 7 shows an example of a process of obtaining the second compressed matrix by compressing (compressing to remove a zero element) the second matrix by column. The second compressed matrix may represent a state in which non-zero elements in the second matrix are arranged by column. For example, in the second compressed matrix shown in FIG. 7, elements in a same column have a same column number, but quantities of elements in different columns may not be equal, which is related to a quantity of non-zero elements in each column of the second matrix. It should be noted that a column number herein is a column number, in the second matrix, of the non-zero element. Similarly, a row number of the non-zero element is a row number, in the second matrix, of the non-zero element. In addition, it should be noted that a quantity of columns of the second compressed matrix is less than or equal to a quantity of columns of the second matrix. For example, when one or more columns of all-zero elements exist in the second matrix, the one or more columns are compressed by entire column. In this case, the quantity of columns of the second compressed matrix is less than the quantity of columns of the second matrix. If at least one non-zero element exists in each column of the second matrix, the quantity of columns of the second compressed matrix is equal to the quantity of columns of the second matrix. The matrix computing manner provided in this application is not affected by this case.

1. A matrix computing method, comprising:
performing, by row, block division on input data of a to-be-multiplied first matrix at a granularity of a subblock whose scale is M×N, to obtain at least one first subblock; and performing, by column, block division on input data of a to-be-multiplied second matrix at a granularity of a subblock whose scale is N×R, to obtain at least one second subblock, wherein M, N, and R are positive integers;
determining one or more target subblock combinations, wherein each target subblock combination comprises one first subblock and one second subblock, and at least one element in the first subblock and at least one element in the second subblock in each target subblock combination are to-be-multiplied elements; and
using each of the one or more target subblock combinations as input data of a matrix computing apparatus, to obtain a product result of the first matrix and the second matrix that is output by the matrix computing apparatus.

2. The method according to claim 1, wherein the first matrix is a sparse matrix, the input data of the first matrix comprises a value of a non-zero element of the first matrix and location information of the non-zero element, and the location information indicates a location of the non-zero element in the first matrix; and
the second matrix is a dense matrix, the input data of the second matrix comprises a value of an element of the second matrix and location information of the element, and the location information indicates a location of the element in the second matrix.

3. The method according to claim 1, wherein the first matrix is a sparse matrix, the input data of the first matrix comprises a value of a non-zero element of the first matrix and location information of the non-zero element, and the location information indicates a location of the non-zero element in the first matrix; and
the second matrix is a sparse matrix, the input data of the second matrix comprises a value of a non-zero element of the second matrix and location information of the non-zero element, and the location information indicates a location of the non-zero element in the second matrix.

4. The method according to claim 1, wherein the input data of the first matrix is a sparse code of the first matrix, and the sparse code is obtained by coding an element in the first matrix.

5. The method according to claim 4, wherein a format of the sparse code comprises a compressed sparse row (CSR) format and a coordinate (COO) format.

6. The method according to claim 1, wherein the second matrix is a sparse matrix, the input data of the second matrix is a sparse code of the second matrix, and the sparse code is obtained by coding an element in the second matrix.

7. The method according to claim 6, wherein a format of the sparse code comprises a compressed sparse column (CSC) format and a coordinate (COO) format.

8. The method according to claim 2, wherein the location information indicates a row number and a column number of the non-zero element, and the to-be-multiplied element means that a column number of an element in the first subblock is the same as a row number of an element in the second subblock.

9. The method according to claim 2, wherein the determining one or more target subblock combinations comprises:
dividing the at least one first subblock and the at least one second subblock into a plurality of subblock combinations, wherein each subblock combination comprises any first subblock and any second subblock;
for each subblock combination, determining a column number range of an element in the first subblock in the subblock combination and a row number range of an element in the second subblock in the subblock combination; and
if there is an intersection between the column number range and the row number range, determining that the subblock combination is the target subblock combination; or
if there is no intersection between the column number range and the row number range, determining that the subblock combination is not the target subblock combination.

10. The method according to claim 1, wherein the matrix computing apparatus is configured to compute a product result of the first subblock and the second subblock based on the input to-be-multiplied elements in the first subblock and the second subblock.

11. The method according to claim 10, wherein the matrix computing apparatus determines the product result of the first matrix and the second matrix in the following manner:
dividing the target subblock combinations into a plurality of sets, wherein one or more first subblocks comprised in one or more target subblock combinations in each set are located in a same row of the first matrix, and one or more second subblocks comprised in the one or more target subblock combinations in each set are located in a same column of the second matrix; and
for each set, sequentially inputting the one or more target subblock combinations in the set into the matrix computing apparatus, and computing, by the matrix computing apparatus, a product result of each target subblock combination, and adding product results of the one or more target subblock combinations in the set, wherein an addition result is one subblock in the product result of the first matrix and the second matrix.

12. A matrix computing apparatus, comprising at least one memory and at least one processor coupled to the at least one memory, wherein the at least one memory stores program instructions for execution by the at least one processor to cause the apparatus to:
compare, based on input data of a to-be-multiplied first submatrix and input data of a to-be-multiplied second submatrix, location information of any non-zero element in the first submatrix with location information of any non-zero element in the second submatrix, to determine one or more pairs of to-be-multiplied elements in the first submatrix and the second submatrix, wherein the input data of the first submatrix comprises a value of an element in the first submatrix and the location information indicating a location, in a first matrix, of the non-zero element in the first submatrix, and the input data of the second submatrix comprises a value of an element in the second submatrix and the location information indicating a location, in a second matrix, of the non-zero element in the second submatrix; and
perform a multiply-add operation on the one or more pairs of to-be-multiplied elements, to obtain a product result of the first submatrix and the second submatrix.

13. The apparatus according to claim 12, wherein the location information comprises a row number and a column number of the non-zero element; and wherein the programming instructions, when executed by the at least one processor, cause the apparatus to:
compare whether a column number of any element in the first submatrix is the same as a row number of any element in the second submatrix; and if the column number of the any element in the first submatrix is the same as the row number of the any element in the second submatrix, determine that the any element in the first submatrix and the any element in the second submatrix are a pair of to-be-multiplied elements, or if the column number of the any element in the first submatrix is different from the row number of the any element in the second submatrix, determine that the any element in the first submatrix and the any element in the second submatrix are not to-be-multiplied elements.

14. The apparatus according to claim 12, wherein the programming instructions, when executed by the at least one processor, cause the apparatus to:
perform, based on any row vector in the first submatrix and any column vector in the second submatrix, the multiply-add operation on a to-be-multiplied element comprised in the row vector and a to-be-multiplied element comprised in the column vector, to obtain a vector multiply-add result of the row vector and the column vector, wherein the vector multiply-add result is an element in the product result of the first submatrix and the second submatrix.

15. The apparatus according to claim 12, wherein the programming instructions, when executed by the at least one processor, cause the apparatus to: add the product result to a third submatrix stored in an accumulator, and write an addition result back to the accumulator.

16. The apparatus according to claim 12, wherein the programming instructions, when executed by the at least one processor, cause the apparatus to the programming instructions, when executed by the at least one processor, cause the apparatus to detect whether the first submatrix and the second submatrix are overlap matrices, wherein the overlap matrices mean that at least one element in the first submatrix and at least one element in the second subblock are to-be-multiplied elements.

17. The apparatus according to claim 16, wherein the to-be-multiplied element means that a column number of an element in the first subblock is the same as a row number of an element in the second subblock.
